(19) United States
(12) Patent Application Publication
(10) Pub. No.: US 2011/0232724 A1
(43) Pub. Date: Sep. 29, 2011

(54) DEVICE FOR PRODUCING ENERGY FROM SOLAR RADIATION

(75) Inventor: Frédéric Duong, F-Pezilla-la-Riviere (FR)

(73) Assignee: Suez Environnement, Paris La Defense (FR)

(21) Appl. No.: 13/122,080

(22) PCT Filed: Sep. 29, 2009
(86) PCT No.: PCT/IB09/54248

§ 371 Date: Jun. 10, 2011

(30) Foreign Application Priority Data
Oct. 2, 2008 (FR) 0805443

(51) Int. Cl. H01L 31/058

(52) U.S. Cl. 136/248

(57) ABSTRACT

Device (D) for producing energy, from solar radiation (RS), intended for a building or industrial construction (1), comprising, on the outside, at least one first wall (2) made up of translucent photovoltaic panels (4) and towards the inside some distance away from the first wall, a dark-coloured opaque second wall (3) positioned facing the first wall (2), a gap (5) being created between the first (2) and the second (3) wall, the energy being produced in electrical form by the photovoltaic panels (4) and in thermal form by the second wall (3) which recovers, in the form of hot air or hot water, some of the radiation that has passed through the first wall (2).

The present invention relates to a device for generating energy, from solar radiation, intended for a building.

Photovoltaic panels integrated into residential, commercial and industrial buildings are widely employed in the context of the development of renewable energy sources, for recovering some of the energy of the sun.

The capture of photons by the atoms of silicon crystals allows a potential difference to be generated. Current is made to flow between the electrodes and it is connected across the terminals of each of the panels installed in a parallel circuit.

Depending on the technology used, the energy-conversion efficiency when converting the incident solar energy into electrical energy that can be fed into the grid lies between 8% and 15% (at the most 20% in the laboratory). The efficiency of electricity generation for commercial exploitation of photovoltaic solar panels is on average 10%.

The panels consist of cells which are embedded in a resin and inserted between two walls made of glass or of a transparent composite.

It is noted that most of the solar radiation (90%) which is received by the photovoltaic panels is either reflected or transformed into heat which is dissipated by convection and radiation to the exterior.

The object of the invention is, above all, to attempt to limit the solar energy lost during the use of photovoltaic solar panels.

According to the invention, a device for generating energy, from solar radiation, intended for a building, is characterized in that it comprises, on the exterior side, at least one first wall composed of translucent photovoltaic panels and, on the interior at a distance from the first wall, a second, opaque, dark-colored wall placed facing the first wall, a free space being created between the first and the second wall, the energy being generated in the form of electricity by the photovoltaic panels and in the form of heat by the second wall, which recovers most of the radiation which has passed through the first wall and allows it to be used, in the form of heat, in addition to the generation of electricity of photovoltaic origin.

Translucent photovoltaic panels exist which can be used for skylights in buildings; in this case they are employed similarly to glazings.

Preferably, the free space between the walls is designed to allow a flow of air to circulate between the first wall and the second wall, so that the photovoltaic panels are cooled. Under these lower-temperature conditions the efficiency of the panels is improved.

The device may comprise a means for capturing air between the first wall and the second wall for a useful thermal purpose, this means for capturing air possibly comprising a pipe connected to a mechanical blower.

The device may also comprise a means of introducing warm air into the free space. According to one embodiment, the means of introducing warm air comprises at least one opening provided in the second wall.

The device may comprise a winding pipe circuit with a circulation of water or any liquid, inserted between the first wall and the second wall.

The second wall may comprise a thermally insulating layer. The second wall may be partially translucent. This second wall may be perforated so as to ensure a permeodynamic flow between the blown sheet of air and the interior of a building.

The device may be arranged so that the thermal energy generated is used to heat the combustion air of a furnace coupled to a generator of electricity.

The device may be arranged so that the thermal energy generated is used to heat a fluid contained in a tank.

Other features and advantages of the invention will become clear in the following description of preferred embodiments with reference to the appended drawings, which however are in no way limiting. In these drawings:

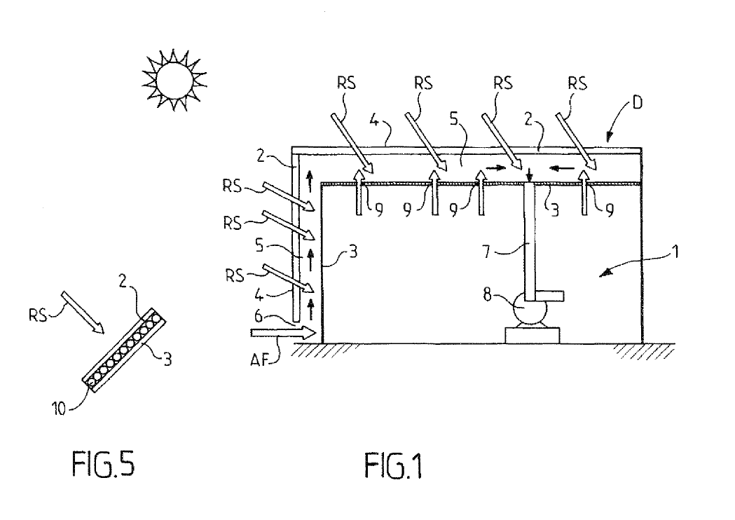

FIG. 1 is a diagram in cross section of a device for generating energy according to the invention;

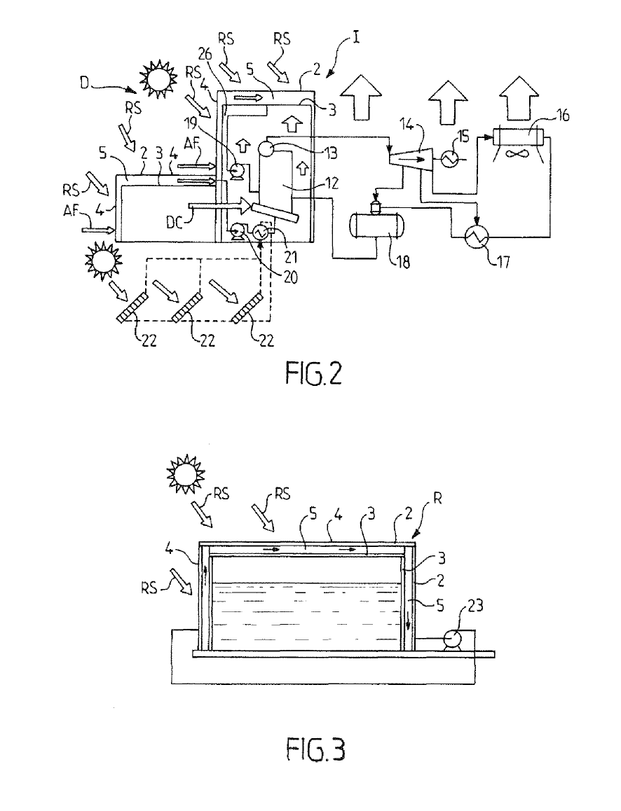

FIG. 2 is a diagram in cross section of a second embodiment of a device for generating energy according to the invention;

FIG. 3 is a diagram in cross section of a third embodiment of a device for generating energy according to the invention;

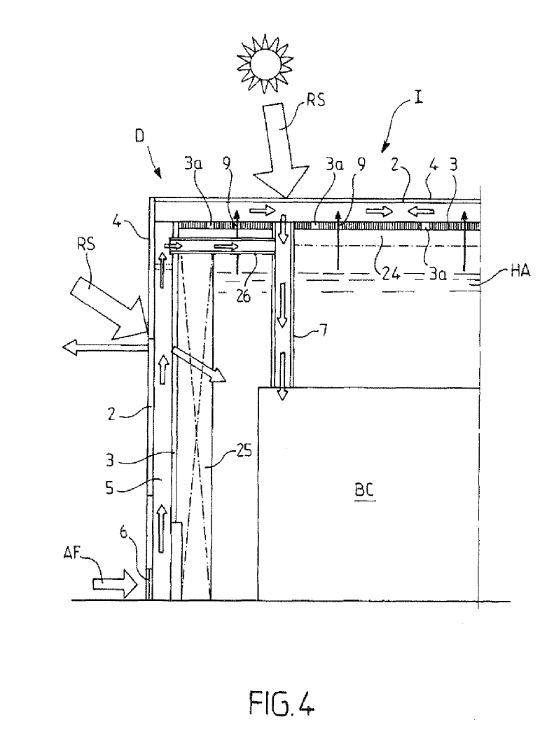

FIG. 4 is a detail, on a larger scale, of the embodiment of the invention in FIG. 2, and

FIG. 5 is a detail, on a larger scale, of a variant of the embodiment in FIG. 1.

In FIG. 1 a portion of a building 1 may be seen. The building 1, which may be an industrial or residential building, is covered with a device D according to the invention. The device D comprises an external wall 2 and an internal wall 3, at a distance from the wall 2.

The external wall 2 is formed by the juxtaposition of translucent or transparent photovoltaic panels 4 placed around and on top of the building 1.

The internal wall 3 is formed by the juxtaposition of dark-colored, for example dark gray, panels made especially of polycarbonate. There is a free space 5 between the external wall 2 and the internal wall 3. Openings 6 are provided in the external wall 2 so as to allow air to enter and circulate in the free space 5. As a variant, the sheet of air in the free space 5 may be static.

Openings 9 are provided in the internal wall 3, when it is employed as a ceiling, placing the region of the free space 5 located above the building 1 in communication with the interior of the building 1.

A pipe 7 passes through the wall 3 and, using a blower 8 placed at the end of the pipe 7, allows air to be extracted from the free space 5 so as to blow it into the building 1.

The device according to the invention operates as follows.

The solar radiation RS reaches the building 1 and the device D and is partially converted into electrical energy by the photovoltaic panels 4. It is recalled that the solar energy received by a horizontal surface may be about 1200 kWh/m²/year in temperate regions and it may reach 1800 kWh/m²/year in southern regions.

A substantial amount of the solar radiation RS passes through the external wall 2 and is absorbed and converted into heat at the dark-colored internal wall 3. This wall 3 heats the air present in the free space 5 via a “greenhouse effect”.

Starting the blower 8 causes cool air AF to enter into the free space 5 from the exterior of the building via the openings 6.

The free space 5 is swept by the air, coming through the openings 6, which progressively heats up on contact with the internal wall 3. A parietodynamic effect is thus obtained.

The openings 9 let air from the interior or exterior of the building penetrate into the free space 5.

The air heated in the space 5 is drawn towards the interior of the building by the blower 8 via the pipe 7. This hot air may be used for burning a solid, liquid or gaseous fuel, or used directly for heating the building 1 or industrial equipment.

The device D according to the invention allows direct generation of photovoltaic electricity and generation of thermal energy to be simultaneously combined on one and the same area. The circulation of air in the space 5 allows the photovoltaic panels 4 to be cooled, making their electricity generation more efficient.

As a variant, illustrated by the detail in FIG. 5, it is possible to install a water circuit in the form of a winding pipe 10 inserted between the two walls 2 and 3, the water, or coolant, of which will be heated by the passage of the air, so as to transport the recovered heat to a remote use.

Another possibility is to thermally insulate the internal wall 3 with respect to the interior of the building 1.

FIG. 2 illustrates the case of a plant I for generating energy by burning waste.

Around the buildings of the plant, a device D similar to that of FIG. 1 is fitted. This aspect is more particularly illustrated in FIG. 4. On the walls and the roofs of the plant I, an external wall 2 and an internal wall 3 are fitted.

The external wall 2 is formed by juxtaposing transparent photovoltaic panels 4. The internal wall 3 is formed by juxtaposing dark-colored polycarbonate panels.

The ceiling part of the internal wall 3 is fastened to metal beams 24 via elements 3a. The beams rest on pillars 25.

There is a free space 5 between the external wall 2 and the internal wall 3. Openings 6 are provided in the external wall 2 so as to allow air AF to enter into the free space 5.

Openings 9 are provided in the internal wall 3, when it is employed as a ceiling, placing the region of the free space 5 located above the buildings of the plant I in communication with the interior of these buildings.

Pipes 7 and 26 allow air to be extracted from the free space 5 to meet the requirements of the plant I, especially to supply a furnace 12, for burning waste or liquid, solid or gaseous fossil fuel, with air.

The plant I functions as follows.

Combustible waste DC is introduced into the furnace 12 equipped with a boiler 13 for generating steam. The steam generated drives a turbine 14 coupled to an A.C. generator 15.

The steam exiting the turbine 14 is then condensed in an air-cooled condenser 16, and the condensate is preheated in a preheater 17 using steam drawn from the turbine 14.

On exiting the preheater 17, the condensate passes through a degassing unit 18, which may additionally be supplied by an extraction from the turbine 14.

On exiting the unit 18, the loop is closed by returning the condensate to the boiler 13.

A blower 19 (FIG. 2) allows, via pipes 7 and 26, hot air to be drawn from the free space 5 into the region located above the furnace 12 and the boiler 13, for it to be injected into the furnace 12 so as to ensure that the secondary air is heated.

Similarly, a blower 20 allows hot air to be drawn from another region of the free space 5. The air drawn-off is heated in a preheater 21 before being injected into the furnace 12 so as to ensure that the primary air, used for the drying and then burning of the waste, is heated.

In this regard solar water heaters 22 (FIG. 2), also equipped on the surface with translucent photovoltaic panels are placed on the roofs of buildings of the plant I. The water from the solar water heaters 22 is used in the preheater 21 to heat the combustion air drawn from the free space 5.

The openings 9 (FIG. 4) allow stratified hot air HA located in the top part of the building, having a temperature possibly reaching 40° C. or higher, present near the furnace 12 and the boiler 13, to penetrate into the free space 5, thereby allowing additional heat to be supplied via the pipe 7. The assembly consisting of the blower 19, the furnace 12 and the boiler 13 in FIG. 2 is schematically represented by a rectangle BC in FIG. 4.

The operational energy balance of the plant for capturing and transforming solar energy is considerably improved. In addition to the electrical energy generated directly by the translucent photovoltaic panels, it is possible to generate heat with about 70% of the total incident solar energy, and to convert this heat into electrical energy with a thermodynamic efficiency of about 25% i.e. 3 times higher than generating electricity simply using conventional photovoltaic panels.

Variants of this hybrid, photovoltaic transducer associated with a thermal transducer, concept are possible. For example, it is possible to provide an external wall 2 and an internal wall 3 only in certain regions of the plant I. In particular it is possible to favor regions where the exposure to sunlight is maximized: south, south-east and south-west facing sides or horizontal or inclined roofs, in the northern hemisphere.

FIG. 3 illustrates the case of a tank R that requires heating, for example a digester, or a vat of liquid effluent.

The tank R comprises a main wall made of concrete or steel. A device D similar to that in FIG. 1 is fitted around the tank R.

In this case, the internal wall 3 is not thermally insulated and allows heat, present in the free space 5, to pass into the material to be heated present inside the tank R.

During sunny periods, the circulation of hot air in the free space 5 is ensured using a blower 23, so as to promote the heating of the interior of the tank and minimize heat loss.

When it is not sunny, especially at night, the blower 23 is stopped, and the layer of static air imprisoned between the two walls provides effective thermal insulation.

The invention has many advantages and especially allows vertical, inclined or horizontal, south, south-east and south-west (for the northern hemisphere) facing areas of buildings to be used to capture solar energy and transform it simultaneously into photovoltaic electricity and into heat which can be recovered in the form of hot air or water.

Transforming thermal energy in a thermodynamic cycle allows electrical energy to be generated using conventional equipment. In the thermodynamic cycle, heat available in water and steam circuits may be used in cogeneration to heat a building or fulfill the requirements of various processes.

The overall energy performance of the combined photovoltaic, thermal, and thermodynamic hybrid device using solar energy is multiplied by a substantial factor relative to photovoltaic or thermal generation on its own.

Architecturally, buildings are transformed into active energy generators, using solar energy, with a very high energy efficiency, to generate electricity and heat.

The invention allows a significant, previously lost, resource to be used, thereby having a substantial economic, environmental and energy impact. At the present time, about 88% of incident solar radiation is not exploited by photovoltaic cells.

Some applications could allow energy-positive units to be obtained, generating both electricity and heat for the implementation of a process, for example a sewage treatment plant (STEP), drying of sludge, etc.

The additional cost of the device relative to photovoltaic panels on their own is not excessive, because the fitting of the hybrid panels is comparable to the fitting of photovoltaic panels on their own.

The device according to the invention has many applications.

It is possible to install the device according to the invention in any residential, commercial and industrial building, optionally associated with a thermodynamic cycle, for the generation of electricity and hot water for hygiene or industrial purposes.

Drying plants, requiring heat in the form of hot air or hot water and a supply of electricity, are also concerned.

In particular, mention may be made of EfW (energy from waste) plants for generating energy from waste, sewage treatment plants (STEP), composting sites, plants for drying or burning and plants for producing refrigerants with absorption or adsorption groups.

1. A device for generating energy, from solar radiation, intended for a building, comprising, on the exterior side, at least one first wall composed of translucent photovoltaic panels and, on the interior at a distance from the first wall, a second, opaque, dark-colored wall placed facing the first wall, a free space being created between the first and the second wall, the energy being generated in the form of electricity by the photovoltaic panels and in the form of heat by the second wall, which recovers some of the radiation which has passed through the first wall.

2. The device as claimed in claim 1, wherein the free space is designed to allow a flow of air to circulate between the first wall and the second wall, so that the photovoltaic panels are cooled and the hot air, which is mechanically captured, used for a thermal or thermodynamic purpose.

3. The device as claimed in claim 1 comprising a means for capturing air between the first wall and the second wall for a useful purpose.

4. The device as claimed in claim 3, wherein the means for capturing air between the first and second walls comprises a pipe.

5. The device according comprising a means of introducing air into the free space.

6. The device as claimed in claim 5, wherein the means of introducing air comprises at least one opening provided in the second wall.

7. The device as claimed in claim 1, comprising a winding pipe with a circulation of water or any thermal fluid, inserted between the first wall and the second wall.

8. The device as claimed in claim 1, wherein the second wall comprises a thermally insulating layer.

9. The device as claimed in claim 1, wherein the second wall is partially translucent.

10. The device as claimed in claim 1, wherein the second wall is perforated.

11. The device as claimed in claim 1, wherein it is arranged so that the thermal energy generated is used to heat the combustion air of a furnace coupled to a generator of electricity.

12. The device as claimed in claim 1, wherein it is arranged so that the thermal energy generated is used to heat a fluid contained in a tank.
